(19) United States
(12) Patent Application Publication
(10) Pub. No.: US 2025/0347001 A1
(43) Pub. Date: Nov. 13, 2025

(54) FILM FORMATION METHOD AND FILM FORMATION APPARATUS

(71) Applicant: Tokyo Electron Limited, Minato-ku, Tokyo (JP)

(72) Inventors: Sena FUJITA, Nirasaki City, Yamanashi (JP); Hiroki MURAKAMI, Nirasaki City, Yamanashi (JP)

(21) Appl. No.: 18/293,489

(22) PCT Filed: Jul. 26, 2022
(86) PCT No.: PCT/JP2022/028804

§ 371 Date: Jan. 17, 2025

(30) Foreign Application Priority Data
Aug. 5, 2021 (JP) 2021-129020

(51) Int. Cl. C23C 16/56; C23C 16/40; C23C 16/455; C23C 16/50; H01J 37/32

(52) U.S. Cl. CPC C23C 16/56; C23C 16/40; C23C 16/45523; C23C 16/50; H01J 37/3244; H01J 2237/334

(57) ABSTRACT

A film formation method includes (A) to (D) as follows: (A) preparing a substrate including a first region with a crystalline structure and a second region with a non-crystalline structure, which are defined on a surface of the substrate; (B) forming a liquid film to cover the first region and the second region; (C) replacing the liquid film on the first region with a first film of the crystalline structure, and replacing the liquid film on the second region with a second film of the non-crystalline structure; and (D) selectively etching one of the first film and the second film with respect to a remaining one of the first film and the second film.

### TECHNICAL FIELD

The present disclosure relates to a film formation method and a film formation apparatus.

### BACKGROUND

A film formation method disclosed in Patent Document 1 includes preparing a substrate including a first region and a second region made of a material different from that of the first region, selectively forming an intermediate film on the second region, adsorbing a self-organized monomolecular film onto the intermediate film, and selectively forming a target film on the first region using the self-organized monomolecular film. The second region has at least two types of surfaces, and the intermediate film is formed over the entire second region. After the formation of the target film, the self-organized monomolecular film and the intermediate film are removed by etching.

A film formation method disclosed in Patent Document 2 includes preparing a substrate including first and second surfaces made of different materials, selectively forming a passivation layer on the first surface, and selectively forming a target layer on the second surface using the passivation layer. The passivation layer is an organic layer, and the organic layer is a polymer layer. A material of the target film remaining on the passivation layer is removed by an etch-back process.

A film formation method disclosed in Patent Document 3 includes forming an a-Si film on a surface of a Si substrate having a partially-formed insulating film, and thermally processing the Si substrate. Heating the Si substrate at a temperature in a range of approximately 500 degrees C. to 700 degrees C. results in the mono-crystallization of a-Si on the insulating film using a contact portion between the Si substrate and the Si film as a seed. By continuing the thermal processing of the Si substrate for a given duration, the entire a-Si film is mono-crystallized.

### PRIOR ART DOCUMENT

### Patent Document

Patent Document 1: Japanese Laid-Open Patent Publication No. 2020-002452
Patent Document 2: Japanese Laid-Open Patent Publication No. 2018-137435
Patent Document 3: Japanese Laid-Open Patent Publication No. 2010-010513

### SUMMARY

One aspect of the present disclosure provides a technology for selectively forming a film on a portion of a substrate including a first region with a crystalline structure and a second region with a non-crystalline structure, which are defined on a surface of the substrate.

According to one aspect of the present disclosure, a film formation method includes (A) to (D) as follows: (A) preparing a substrate including a first region with a crystalline structure and a second region with a non-crystalline structure, which are defined on a surface of the substrate; (B) forming a liquid film to cover the first region and the second region; (C) replacing the liquid film on the first region with a first film of the crystalline structure, and replacing the liquid film on the second region with a second film of the non-crystalline structure; and (D) selectively etching one of the first film and the second film with respect to a remaining one of the first film and the second film.

According to the present disclosure, it is possible to selectively form a film on a portion of a substrate including a first region with a crystalline structure and a second region with a non-crystalline structure, which are defined on a surface of the substrate.

### BRIEF DESCRIPTION OF DRAWINGS

FIG. 1 is a flowchart illustrating a film formation method according to one embodiment.

FIG. 2 is a flowchart illustrating an example of a subroutine executed in step S12 of FIG. 1.

FIG. 3A is a cross-sectional view illustrating an example of step S11 of FIG. 1.

FIG. 3B is a cross-sectional view illustrating an example of step S121 of FIG. 2.

FIG. 3C is a cross-sectional view illustrating an example of step S122 of FIG. 2.

FIG. 3D is a cross-sectional view illustrating an example of step S14 of FIG. 1.

FIG. 4 is a flowchart illustrating a first modification of a subroutine executed in step S12 of FIG. 1.

FIG. 5 is a flowchart illustrating a second modification of a subroutine executed in step S12 of FIG. 1.

FIG. 6 is a cross-sectional view illustrating an example of a substrate immediately before step S128 of FIG. 5.

FIG. 7 is a cross-sectional view illustrating a film formation apparatus according to one embodiment.

FIG. 8 is an SEM photograph illustrating a substrate after the processing in Example 1.

FIG. 9 is an SEM photograph illustrating a substrate after the processing in Example 2.

FIG. 10 is an SEM photograph illustrating a substrate before the processing in Example 4.

FIG. 11 is an SEM photograph illustrating the substrate after the processing in Example 4.

FIG. 12 is an SEM photograph illustrating a substrate after the processing in Example 6.

FIG. 13 is a cross-sectional view illustrating an example of a width A1 of a first region and a width A2 of a first film.

### DETAILED DESCRIPTION

Hereinafter, embodiments of the present disclosure will be described with reference to the accompanying drawings. In addition, in each drawing, the same reference numerals will be given to the same or corresponding components, and descriptions thereof may be omitted.

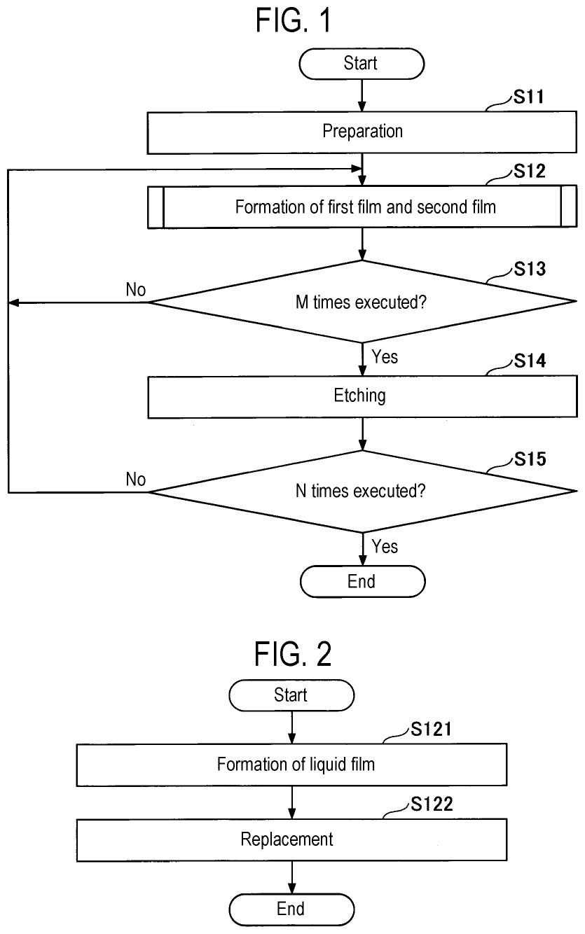

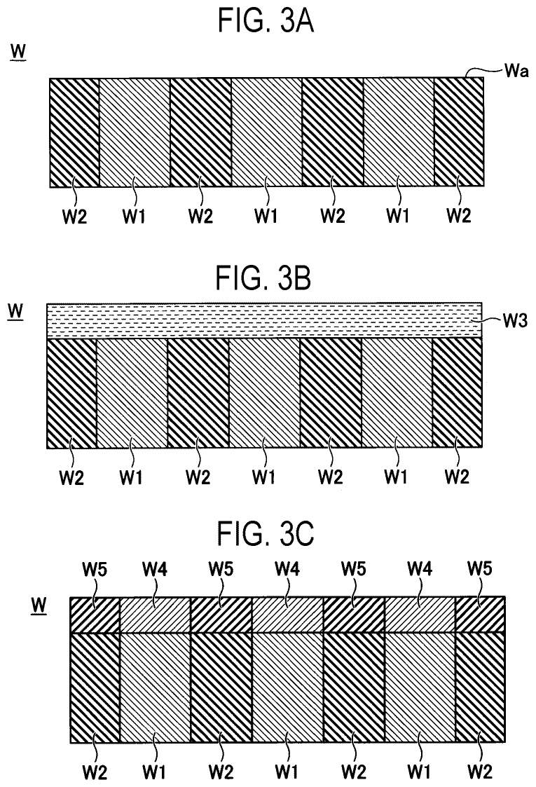

A film formation method according to one embodiment will be described with reference to FIGS. 1, 2, and 3A to 3D. The film formation method includes steps S11 to S15 illustrated in FIG. 1. In step S11 of FIG. 1, a substrate W is prepared, as illustrated in FIG. 3A. The substrate W includes a first region W1 with a crystalline structure and a second region W2 with a non-crystalline structure, which are defined on a surface Wa of the substrate W. The surface Wa of the substrate W is a flat surface as illustrated in FIG. 3A in the present embodiment, but may also be an uneven surface, or may have a stepped portion at a boundary between the first region W1 and the second region W2. When a size of the stepped portion is small, it is possible to form a first film W4 and a second film W5. In addition, although not illustrated, the substrate W may include a third region in the surface, which is made of a material different from those of the first region W1 and the second region W2.

The first region W1 is constituted with a first base film with a crystalline structure. The first base film is, for example, a film containing at least one metal element selected from a group consisting of Cu, Co, Ru, Mo, W, and Ti. The first base film is a metal film, a metal oxide film, or a metal nitride film. The metal film is, for example, a Cu film, a Co film, a Ru film, a Mo film, a W film, or a Ti film. The metal nitride film is, for example, a TiN film. Here, the TIN film refers to a film containing titanium (Ti) and nitrogen (N). An atomic ratio of Ti to N in the TiN film is not limited to 1:1.

The second region W2 is constituted with a second base film with a non-crystalline structure. The second base film is, for example, an α-Si film, a SiO film, a SiN film, a SiOC film, a SiON film, a SiOCN film, a SiBN film, a SiOBN film, an AlO film, a B film, or a BN film. Here, the SiO film refers to a film containing silicon (Si) and oxygen (O). An atomic ratio of Si to O in the SiO film is typically 1:2, but is not limited to 1:2. Similarly, the SiN film, SiOC film, the SiON film, the SiOCN film, the SiBN film, the SiOBN film, the AlO film and the BN film also refer that it contains each element, and is not limited to the stoichiometric ratio.

The second base film is, for example, an interlayer insulating film. The interlayer insulating film may be a low-k film. The interlayer insulating film has a recess on the surface Wa of the substrate W. The recess is a trench, a contact hole or a via hole. The first base film is formed in the recess. The first base film is, for example, a conductive film, a barrier film, or a cap film.

Step S12 of FIG. 1 includes steps S121 and S122 illustrated in FIG. 2, for example. First, in step S121, a liquid film W3 is formed to cover the first region W1 and the second region W2, as illustrated in FIG. 3B. The liquid film W3 contains, for example, a metal element, and specifically contains, for example, a metal halide. In step S121 above, the liquid film W3 is formed by, for example, a reaction between a raw material gas containing a metal halide and a reaction gas that reacts with the raw material gas. The raw material gas is, for example, a TiCl₄ gas, and the reaction gas is, for example, a H₂ gas.

The TiCl₄ gas and the H₂ gas are generally used to form a Ti film. The Ti film is formed by, for example, a chemical vapor deposition (CVD) method or an atomic layer deposition (ALD) method. In the CVD method, the TiCl₄ gas and the H₂ gas are simultaneously supplied to the substrate W. On the other hand, in the ALD method, the TiCl₄ gas and the H₂ gas are alternately supplied to the substrate W. According to the CVD method or the ALD method, it is estimated that the following equations (1) to (3) contribute to the formation of the Ti film.

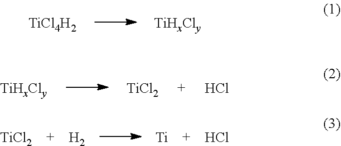

In addition, in the above equations (2) and (3), TiCl₂ may also be TiCl or TiCl₃.

In the formation of the Ti film, a temperature of the substrate W is controlled to 400 degrees C. or higher. As a result, the reactions in the above equations (1) to (3) proceed sequentially, leading to the formation of the Ti film.

On the other hand, in the formation of the liquid film W3, the temperature of the substrate is, for example, 350 degrees C. or lower. When the temperature of the substrate is 350 degrees C. or lower, the reactions in the above equations (2) and (3) are suppressed, leading to the formation of the liquid film W3 containing TiHₓCl_{y}. The liquid film W3 may also contain Ti, TiCl, TiCl₂, TiCl₃, or TiCl₄.

The lower the temperature of the substrate, the more the reactions in the above equations (2) and (3) are suppressed. The temperature of the substrate in step S121 above may be specifically 250 degrees C. or lower, and may be more specifically 150 degrees C. or lower. The temperature of the substrate W in step S121 above just needs to be lower than a decomposition point of the liquid film W3. In addition, the temperature of the substrate in step S121 above may be specifically −100 degrees C. or higher, and may be more specifically 20 degrees C. or higher.

The raw material gas is not limited to the TiCl₄ gas. The raw material gas may be any gas containing a metal halide such as, for example, a WCl4 gas, a VCl₄ gas, an AlCl₃ gas, a MoCl₅ gas, or a SnCl₄ gas. The raw material gas may contain a halogen, and may contain, as halogen, bromine (Br), iodine (I), or fluorine (F), instead of chlorine (Cl). For these raw material gases, reactions similar to the above equation (1) mainly proceed when the temperature of the substrate W is lower than the decomposition point of the liquid film W3, resulting in the formation of the liquid film W3.

The reaction gas is not limited to the H₂ gas. The reaction gas may be any gas capable of forming the liquid film W3 by reacting with the raw material gas. For example, the reaction gas may be a D₂ gas. The reaction gas may also be supplied together with a noble gas such as an argon gas.

In step S121 above, for example, the raw material gas and the reaction gas are simultaneously supplied to the substrate W. In this case, the raw material gas and the reaction gas may be plasmarized. Plasmarization may facilitate the reaction between the raw material gas and the reaction gas. Further, plasmarization makes it easier to form the liquid film W3 at low substrate temperatures.

The raw material gas and the reaction gas are simultaneously supplied to the substrate W in the present embodiment, but the raw material gas and the reaction gas may be alternately supplied.

In the latter case, the reaction gas may be plasmarized. Plasmarization may facilitate the reaction between the raw material gas and the reaction gas. Further, plasmarization makes it easier to form the liquid film W3 at low substrate temperatures.

In addition, in step S121 above, only the raw material gas may be supplied to the substrate W.

In step S122 of FIG. 2, the liquid film W3 on the first region W1 is replaced with the first film W4 with a crystalline structure, and the liquid film W3 on the second region W2 is replaced with the second film W5 with a non-crystalline structure, as illustrated in FIG. 3C. A structural difference between the first base film and the second base film may be reflected in a structural difference between the first film W4 and the second film W5. The first film W4 is formed using the crystalline structure of the first region W1 as a seed, thus having the crystalline structure. The second film W5 is formed using the non-crystalline structure of the second region W2 as a seed, thus having the non-crystalline structure.

In step S122 above, to reflect the structural difference between the first base film and the second base film in the structural difference between the first film W4 and the second film W5, the temperature of the substrate W is controlled to, for example, 350 degrees C. or lower. When the temperature of the substrate is 350 degrees C. or lower, the crystallization of the second film W5 may be suppressed. The temperature of the substrate in step S122 above may be specifically 250 degrees C. or lower, and may be more specifically 150 degrees C. or lower. The temperature of the substrate in step S122 above may be specifically 20 degrees C. or higher, and may be more specifically 50 degrees C. or higher, from the viewpoint of facilitating the solidification of the liquid film W3.

In step S122 above, for example, a processing gas that reacts with the liquid film W3 is used to replace the liquid film W3 on the first region W1 with the first film W4 with a crystalline structure and to replace the liquid film W3 on the second region W2 with the second film W5 with a non-crystalline structure. The processing gas chemically reacts with the liquid film W3. A chemical change gradually progresses from a surface of the liquid film W3.

In step S122 above, the processing gas may be plasmarized. Plasmarization may facilitate the reaction between the processing gas and the liquid film W3. The processing gas may also be supplied together with a noble gas such as an argon gas.

The processing gas contains an element that is introduced into the liquid film W3 by the reaction with the liquid film W3, for example. In other words, the processing gas contains an element to be introduced into the liquid film W3. For example, oxygen in the processing gas is introduced into the liquid film W3, resulting in the acquisition of the first film W4 and the second film W5. In this case, the first film W4 and the second film W5 are oxides. Alternatively, nitrogen in the processing gas is introduced into the liquid film W3, resulting in the acquisition of the first film W4 and the second film W5. In this case, the first film W4 and the second film W5 are nitrides. Any element may be used as long as the respective element in the processing gas can be introduced into the liquid film W3. During this process, the respective element constituting the liquid film W3 may be degassed.

The processing gas is, for example, an oxygen-containing gas. The oxygen-containing gas contains oxygen as the element to be introduced into the liquid film W3. The oxygen-containing gas may further contain nitrogen as the element to be introduced into the liquid film W3. Examples of the oxygen-containing gas include an O₂ gas, an O₃ gas, a H₂O gas, a NO gas, and a N₂O gas.

The processing gas may also be a nitrogen-containing gas. The nitrogen-containing gas contains nitrogen as the element to be introduced into the liquid film W3. Examples of the nitrogen-containing gas include a N₂ gas, a NH₃ gas, a N₂H₄ gas, and a N₂H₂ gas.

The processing gas may also be a hydride gas. The hydride gas contains an element bound to hydrogen as the element to be introduced into the liquid film W3, such as Si, Ge, B, C, or P. Examples of the hydride gas include a hydrocarbon gas such as a SiH₄ gas, a Si₂H₆ gas, a GeH₄ gas, a B₂H₆ gas or a C₂H₄ gas, and a PH₃ gas.

The processing gas may allow any element constituting the liquid film W3 to be degassed by reacting with the liquid film W3. For example, the processing gas may be a reducing gas. The reducing gas is, for example, a hydrogen (H₂) gas or a deuterium (D₂) gas.

The processing gas contains one or more gas selected from oxygen, nitrogen, hydrogen, deuterium, and hydride.

In step S13 of FIG. 1, it is determined whether or not a first cycle has been executed M times (M is an integer of 1 or more). One round of first cycle includes steps S121 and S122 above. M may be an integer of 2 or more, and steps S121 and S122 above may be repeated. A film thickness of the liquid film W3 formed in one round of step S12 may be thinned, making it easier to reflect the structure of the first and second base films in the liquid film W3.

When the number of executions of the first cycle is less than M (NO in step S13), since the film thicknesses of the first film W4 and the second film W5 are less than a target value, the first cycle is executed again. M is not particularly limited, but is, for example, in a range of 2 to 100, specifically, in a range of 5 to 20.

On the other hand, when the number of executions of the first cycle reaches M (YES in step S13), since the film thicknesses of the first film W4 and the second film W5 have reached the target value, processing after step S14 is executed.

In step S14 of FIG. 1, one of the first film W4 with a crystalline structure and the second film W5 with a non-crystalline structure is selectively etched with respect to the other. In general, the crystalline structure has higher resistance against etching with respect to the non-crystalline structure of the same composition. Therefore, the second film W5 may be selectively etched. As illustrated in FIG. 3D, the first film W4 may remain even after completely removing the second film W5, which forms an uneven structure.

In addition, in step S14 above, the first film W4, rather than the second film W5, may be selectively etched. In this case, the second film W5 may remain even after completely removing the first film W4, which forms an uneven structure.

The etching may be either isotropic etching or anisotropic etching, but the anisotropic etching is desirable. Further, the etching may be either dry etching or wet etching, but the dry etching is desirable.

In the dry etching, an etching gas is supplied to the substrate W. The etching gas is, for example, a halogen-containing gas. In a case of thermal dry etching, for example, a Cl₂ gas, a ClF₃ gas, a F₂ Gas, or a HF gas is used as the etching gas. On the other hand, in a case of plasma dry etching, for example, a Cl₂ gas, a CF₄ gas, a CHF₃ gas, a C₄F₈ gas, a NF₃ gas or a SF₆ gas is used as a plasmarized etching gas. The etching gas may also be supplied together with an oxygen gas, a hydrogen gas, or a nitrogen gas.

In a case of atomic layer etching (ALE), the etching gas and the reaction gas may be alternately supplied. For example, the etching gas may be a Cl₂ gas, a CF₄ gas, a C₄F₈ gas, or a WF₆ gas, and the reaction gas may be an Ar gas, a He gas, a H₂ gas, or a BCl₃ gas. The reaction gas may be supplied in a plasmarized state.

In step S14 above, in order to prevent the crystallization of the second film W5, the temperature of the substrate W is controlled to, for example, 350 degrees C. or lower. The temperature of the substrate in step S14 above may be specifically 250 degrees C. or lower, and may be more specifically 150 degrees C. or lower. From the viewpoint of shortening the etching time, the temperature of the substrate in step S14 above may be specifically 20 degrees C. or higher, and may be more specifically 50 degrees C. or higher.

In step S15 of FIG. 1, it is determined whether or not a second cycle has been executed N times (N is an integer of 1 or more). One round of second cycle includes M first cycles and step S14 executed after the M first cycles. N may be an integer of 2 or more, and steps S12 to S14 may be repeated.

When the number of executions of the second cycle is less than N (NO in step S15), since the film thickness of the first film W4 or the second film W5 is less than a target value, the second cycle is executed again. N is not particularly limited, but is, for example, in a range of 1 to 10, specifically in a range of 1 to 5.

On the other hand, when the number of executions of the second cycle reaches N (YES in step S15), since the film thickness of the first film W4 or the second film W5 has reached the target value, the current processing is terminated.

While steps S12 to S15 of FIG. 1 are executed, the substrate W may be continuously accommodated in the same processing container. Since the substrate W is not unloaded out of the processing container, atmosphere around the substrate W may be maintained in a vacuum atmosphere, which may prevent the oxidation of the substrate W.

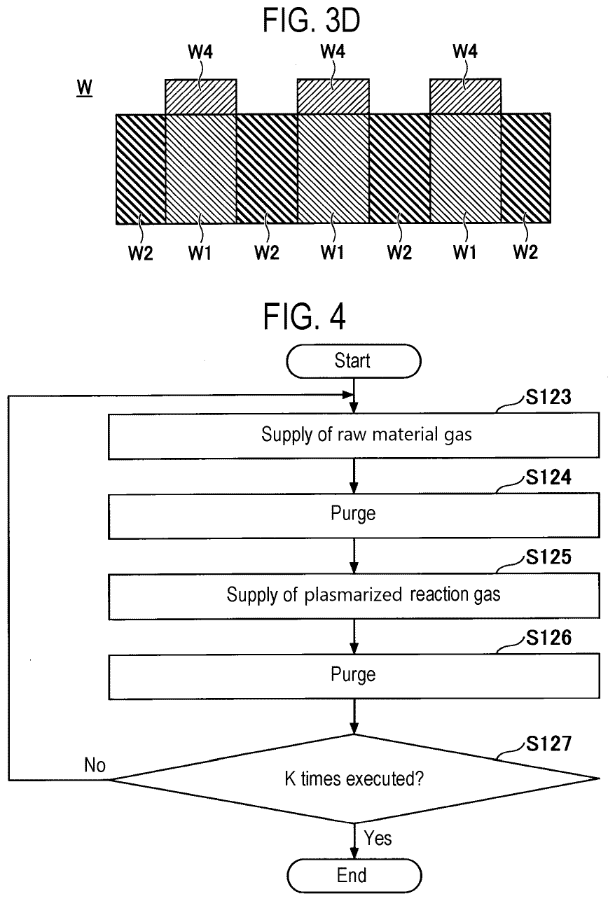

Next, a first modification of a subroutine executed in step S12 of FIG. 1 will be described with reference to FIG. 4. Step S12 may include steps S123 to S127 illustrated in FIG. 4, instead of steps S121 and S122 illustrated in FIG. 2, and may use the ALD method to form the first film W4 with a crystalline structure on the first region W1 and form the second film W5 with a non-crystalline structure on the second region W2.

In the ALD method, unlike the CVD method, a raw material gas containing a metal element and a plasmarized reaction gas are alternately supplied to the surface Wa of the substrate W. In the CVD method, the raw material gas containing a metal element and the plasmarized reaction gas are simultaneously supplied to the surface Wa of the substrate W. According to the CVD method, even if the temperature of the substrate W is 150 degrees C. or lower, the first film W4 with a crystalline structure is formed over the entire surface Wa of the substrate W.

In the ALD method, unlike the CVD method, the raw material gas containing a metal element and the plasmarized reaction gas are alternately supplied to the surface Wa of the substrate W. In the ALD method, unlike the CVD method, the first film W4 and the second film W5 are grown discontinuously in small increments, so that the structural difference between the first base film and the second base film may be reflected in the structural difference between the first film W4 and the second film W5.

In the ALD method, in order to reflect the structural difference between the first base film and the second base film in the structural difference between the first film W4 and the second film W5, the temperature of the substrate W is controlled to, for example, 350 degrees C. or lower. In steps S123 to S126 below, when the temperature of the substrate is 350 degrees C. or lower, the crystallization of the second film W5 may be suppressed. The temperature of the substrate in steps S123 to S126 below may be specifically 250 degrees C. or higher from the viewpoint of facilitating the reaction between the raw material gas and the reaction gas.

In step S123 of FIG. 4, the raw material gas containing a metal element is supplied to the surface Wa of the substrate W. The raw material gas is chemically adsorbed onto the surface Wa of the substrate W. The raw material gas contains, for example, a metal halide or an organic metal. The metal halide is not particularly limited, but may be TiCl₄, VCl⁴, MoCl₅, or WF₆. The halogen may be any of chlorine (Cl), bromine (Br), iodine (I), and fluorine (F). The organic metal is not particularly limited, but may be Ti[N(CH₃)₂]₄(TDMAT: Tetrakis(dimethylamino)titanium), Ti[N(C₂H₅)(CH₃)]₄((TEMAT: Tetrakis(ethylmethylamino)titanium), Ru(C₅H₅)₂(bis(cyclopentadienyl)ruthenium), Ru(C₅H₄C₂H₅)₂(bis(ethylcyclopentadienyl)ruthenium), Mo[N(CH₃)₂]₄(tetrakis(dimethylamino)molybdenum), Ta(OC₂H₅)₅(pentaethoxytantalum), or W(CO)₆(Hexacarbonyltungsten).

In step S124 of FIG. 4, a purge gas is supplied to the surface Wa of the substrate W. The purge gas purges the excess raw material gas that has not been chemically adsorbed onto the surface Wa of the substrate W in step S123 above. For example, a noble gas such as an Ar gas is used as the purge gas. Since the noble gas is an inert gas, it may be supplied not only in step S124 above but also in all steps S123 to S126.

In step S125 of FIG. 4, the plasmarized reaction gas is supplied to the surface Wa of the substrate W. The reaction gas is, for example, an oxygen-containing gas, a nitrogen-containing gas, or a hydrogen-containing gas. The oxygen-containing gas oxidizes a metal element contained in the raw material gas to form an oxide film. The oxygen-containing gas is, for example, an O₂ gas, an O₃ gas, or a H₂O gas. The nitrogen-containing gas nitrides a metal element contained in the raw material gas to form a nitride film. The nitrogen-containing gas is, for example, a NH₃ gas, a N₂ gas, or a N₂H₂ gas. The hydrogen-containing gas reduces the raw material gas to form a metal film. The hydrogen-containing gas is, for example, a H₂ gas, a SiH₄ gas, or a B₂H₆ gas.

In addition, the reaction gas may be supplied not only in step S125 above but also in all steps S123 to S126. However, the plasmarization of the reaction gas occurs only in step S125 above. This is because the plasmarized reaction gas reacts with the raw material gas adsorbed onto the surface Wa of the substrate W.

In step S126 of FIG. 4, a purge gas is supplied to the surface Wa of the substrate W. The purge gas purges the excess reaction gas that has not been chemically adsorbed onto the surface Wa of the substrate W in step S125 above. For example, a noble gas such as an Ar gas is used as the purge gas. Since the noble gas is an inert gas, it may be supplied not only in step S126 above but also in all steps S123 to S126, as described above.

In step S127 of FIG. 4, it is determined whether or not steps S123 to S126 above have been executed K times (K is an integer of 1 or more). K may be an integer of 2 or more, and steps S123 to S126 above may be repeated. This makes it possible to increase the film thicknesses of the first film W4 and the second film W5.

When the number of executions of steps S123 to S126 above is less than K (NO in step S127), since the film thicknesses of the first film W4 and the second film W5 are less than a target value, steps S123 to S126 above are executed again. K is not particularly limited, but is, for example, in a range of 2 to 1000, specifically in a range of 50 to 500.

On the other hand, when the number of executions of steps S123 to S126 reaches K (YES in step S127), since the film thicknesses of the first film W4 and the second film W5 have reached the target value, the current processing is terminated.

However, in steps S123 to S127 above, as described above, the ALD method is used to form the first film W4 with a crystalline structure on the first region W1 and form the second film W5 with a non-crystalline structure on the second region W2, but the technology of the present disclosure is not limited thereto. In steps S123 to S127 above, the second film W5 with a non-crystalline structure may be formed on both the first region W1 and the second region W2, as illustrated in FIG. 6. When the temperature of the substrate is low in steps S123 to S127 above, the second film W5 may be formed on both the first region W1 and the second region W2.

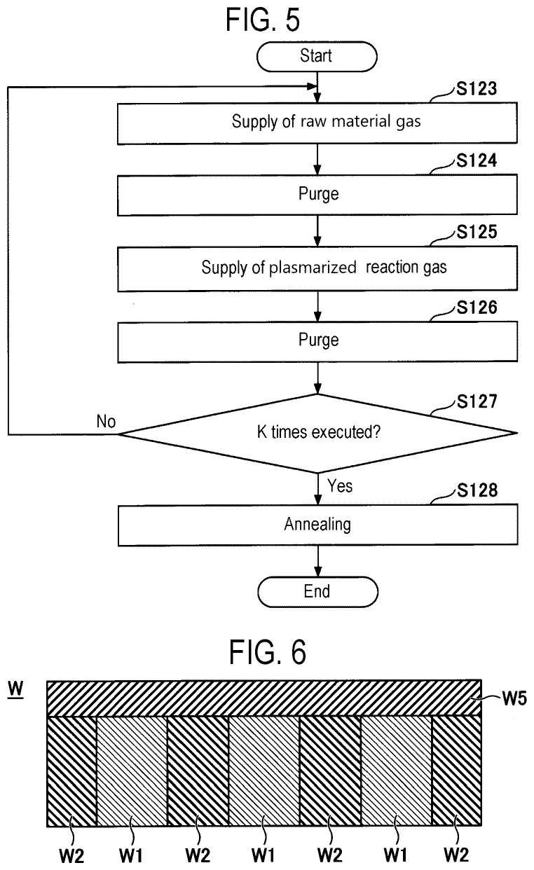

Therefore, step S12 of FIG. 1 may include step S128 below after steps S123 to S127 above, as illustrated in FIG. 5. In step S128, by heating the substrate W, the second film W5 on the first region W1 is replaced with the first film W4. The first film W4 is crystallized using the crystalline structure of the first region W1 as a seed. As a result, a substrate in which the first film W4 is formed on the first region W1 and the second film W5 is formed on the second region W2, is obtained.

In step S128 above, in order to prevent the crystallization of the second film W5 on the second region W2, the temperature of the substrate W is controlled to, for example, 350 degrees C. or lower. The temperature of the substrate in step S128 above may be 250 degrees C. or higher from the viewpoint of facilitating the reaction of replacing the second film W5 on the first region W1 with the first film W4.

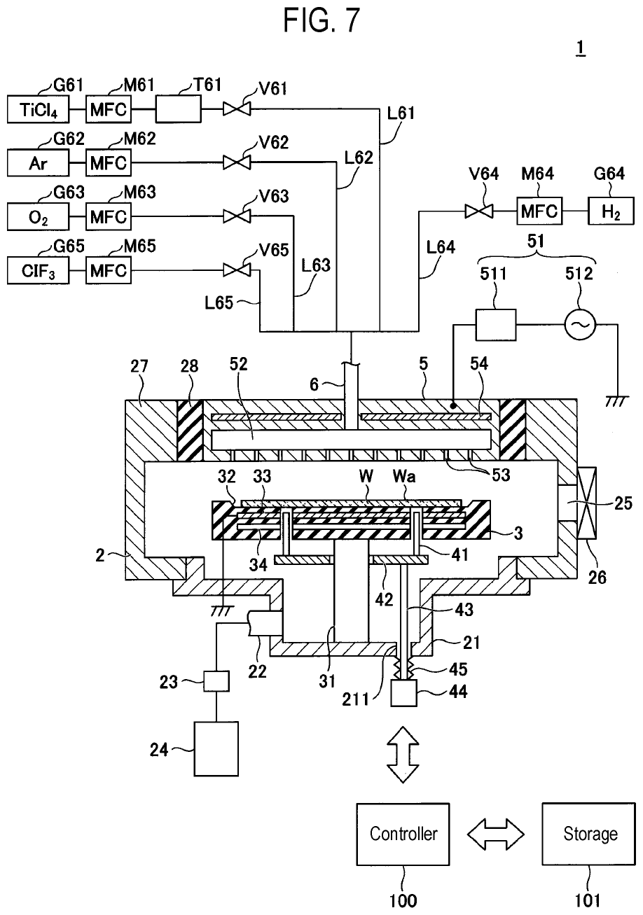

Next, a film formation apparatus 1 will be described with reference to FIG. 7. The film formation apparatus 1 includes a substantially cylindrical airtight processing container 2. An exhaust chamber 21 is provided in the central portion of a bottom wall of the processing container 2. The exhaust chamber 21 has, for example, a substantially cylindrical shape that protrudes downward. An exhaust pipe 22 is connected to the exhaust chamber 21, for example, to the lateral side of the exhaust chamber 21.

An exhauster 24 is connected to the exhaust pipe 22 via a pressure adjuster 23. The pressure adjuster 23 includes, for example, a pressure adjustment valve such as a butterfly valve. The exhaust pipe 22 is configured to be capable of depressurizing the interior of the processing container 2 by the exhauster 24. A transfer port 25 is provided on the lateral side of the processing container 2. The transfer port 25 is opened and closed by a gate valve 26. Loading and unloading of the substrate W between the interior of the processing container 2 and a transfer chamber (not illustrated) are performed via the transfer port 25.

A stage 3 is provided inside the processing container 2. The stage 3 is a holder that horizontally holds the substrate W with the surface Wa of the substrate W oriented upward. The stage 3 is formed in a substantially circular shape in a plan view and is supported by a supporting member 31. A substantially circular recess 32 is formed on a surface of the stage 3 to place the substrate W having a diameter of, for example, 300 mm thereon. The recess 32 has an inner diameter slightly larger than a diameter of the substrate W. The recess 32 is configured, for example, to have substantially the same depth as the thickness of the substrate W. The stage 3 is made of a ceramic material such as aluminum nitride (AlN). Further, the stage 3 may be formed of a metallic material such as nickel (Ni). In addition, instead of the recess 32, a guide ring for guiding the substrate W may be provided on a peripheral portion of the surface of the stage 3.

For example, a grounded lower electrode 33 is embedded in the stage 3. A heating mechanism 34 is also embedded below the lower electrode 33. The heating mechanism 34 heats the substrate W placed on the stage 3 to a set temperature by receiving power supplied from a power supply (not illustrated) based on a control signal from a controller 100. In a case where the entire stage 3 is made of a metal, the entire stage 3 functions as a lower electrode. Thus, it is not necessary to embed the lower electrode 33 in the stage 3. The stage 3 is provided with a plurality of (for example, three) lifting pins 41 for holding and vertically moving the substrate W placed on the stage 3. A material of the lifting pins 41 may be, for example, ceramics such as alumina (Al₂O₃) or quartz. Lower ends of the lifting pins 41 are attached to a supporting plate 42. The supporting plate 42 is connected to a lifting mechanism 44 provided outside the processing container 2 via a lifting shaft 43.

The lifting mechanism 44 is located, for example, beneath the exhaust chamber 21. A bellows 45 is interposed between an opening 211 for the lifting shaft 43 formed in the underside of the exhaust chamber 21 and the lifting mechanism 44. The supporting plate 42 may have a shape in which the supporting plate 42 can vertically move without interfering with the supporting member 31 of the stage 3. The lifting pins 41 are configured to vertically move from below the surface of the stage 3 to above the surface of the stage 3 by the lifting mechanism 44.

A gas supplier 5 is provided in a ceiling wall 27 of the processing container 2 via an insulating member 28. The gas supplier 5 constitutes an upper electrode and is provided to face the lower electrode 33. A radio-frequency power supply 512 is connected to the gas supplier 5 via a matcher 511. The radio-frequency power supply 512 supplies radio-frequency power in a range of 450 kHz to 2.45 GHz, specifically in a range of 450 kHz to 100 MHz to the upper electrode (the gas supplier 5). As a result, a radio-frequency electric field is created between the upper electrode (the gas supplier 5) and the lower electrode 33, which generates a capacitively coupled plasma. A plasma generator 51 includes the matcher 511 and the radio-frequency power supply 512. In addition, the plasma generator 51 may generate any plasma other than the capacitively coupled plasma, such as inductively coupled plasma.

The gas supplier 5 includes a hollow gas supply chamber 52. A large number of holes 53 for dispersedly supplying a processing gas into the processing container 2 are evenly arranged in, for example, the underside of the gas supply chamber 52. A heating mechanism 54 is embedded in the gas suppler 5, for example, above the gas supply chamber 52. The heating mechanism 54 is heated to a set temperature with power fed from a power supply (not illustrated) based on a control signal from the controller 100.

A gas supply path 6 is provided in the gas supply chamber 52. The gas supply path 6 communicates with the gas supply chamber 52. The gas supply path 6 is connected at the upstream side to gas sources G61, G62, G63, G64, and G65 via gas lines L61, L62, L63, L64, and L65, respectively.

The gas source G61 is a source of a TiCl₄ gas and is connected to the gas supply path 6 via the gas line L61. The gas line L61 is provided with a mass flow controller M61, a storage tank T61, and a valve V61 in this order from the side of the gas source G61. The mass flow controller M61 controls a flow rate of the TiCl₄ gas flowing through the gas line L61. The storage tank T61 stores the TiCl₄ gas supplied from the gas source G61 via the gas line L61 with the valve V61 closed, which increases a pressure of the TiCl₄ gas inside the storage tank T61. The valve V61 performs the supply/cutoff of the TiCl₄ gas to the gas supply path 6 by the opening/closing operation thereof.

The gas source G62 is a source of an Ar gas and is connected to the gas supply path 6 via the gas line L62. The gas line L62 is provided with a mass flow controller M62 and a valve V62 in this order from the side of the gas source G62. The mass flow controller M62 controls a flow rate of the Ar gas flowing through the gas line L62. The valve V62 performs the supply/cutoff of the Ar gas to the gas supply path 6 by the opening/closing operation thereof.

The gas source G63 is a source of an O₂ gas and is connected to the gas supply path 6 via the gas line L63. The gas line L63 is provided with a mass flow controller M63 and a valve V63 in this order from the side of the gas source G63. The mass flow controller M63 controls a flow rate of the O₂ gas flowing through the gas line L63. The valve V63 performs the supply/cutoff of the O₂ gas to the gas supply path 6 by the opening/closing operation thereof.

The gas source G64 is a source of a H₂ gas and is connected to the gas supply path 6 via the gas line L64. The gas line L64 is provided with a mass flow controller M64 and a valve V64 in this order from the side of the gas source G64. The mass flow controller M64 controls a flow rate of the H₂ gas flowing through the gas line L64. The valve V64 performs the supply/cutoff of the H₂ gas to the gas supply path 6 by the opening/closing operation thereof.

The gas source G65 is a source of a ClF₃ gas and is connected to the gas supply path 6 via the gas line L65. The gas line L65 is provided with a mass flow controller M65 and a valve V65 in this order from the side of the gas source G65. The mass flow controller M65 controls a flow rate of the ClF₃ gas flowing through the gas line L65. The valve V65 performs the supply/cutoff of the ClF₃ gas to the gas supply path 6 by the opening/closing operation thereof.

The film formation apparatus 1 includes the controller 100 and a storage 101. The controller 100 includes a CPU, a RAM, a ROM, and the like (all not illustrated), and comprehensively controls the film formation apparatus 1, for example, by causing the CPU to execute a computer program stored in the ROM or the storage 101. Specifically, the controller 100 causes the CPU to execute the control program stored in the storage 101 to control the operation of each component of the film formation apparatus 1, thereby executing, for example, a film forming process on the substrate W.

Next, referring again to FIG. 7, the operation of the film formation apparatus 1 will be described. First, the controller 100 opens the gate valve 26 to transfer the substrate W into the processing container 2 by a transfer mechanism, and then place the substrate on the stage 3. The substrate W is horizontally placed on the stage 3 with the surface Wa oriented upward. After retracting the transfer mechanism from the processing container 2, the controller 100 closes the gate valve 26. Subsequently, the controller 100 heats the substrate W to a predetermined temperature by the heating mechanism 34 of the stage 3, and adjusts the interior of the processing container 2 to a predetermined pressure by the pressure adjuster 23. For example, loading the substrate W into the processing container 2 is included in step S11 of FIG. 1.

Subsequently, the controller 100 executes step S12 of FIG. 1. Step S12 includes steps S121 and S122 illustrated in FIG. 2, for example. First, in step S121 of FIG. 2, the controller 100 opens the valves V61, V62 and V64 to simultaneously supply the TiCl₄ gas, the Ar gas and the H₂ gas into the processing container 2. The valves V63 and V65 remain closed. With the reaction between the TiCl₄ gas and the H₂ gas, the liquid film W3 such as TiHₓCl_{y} is supplied to the surface Wa of the substrate W.

Specific processing conditions for step S121 above are, for example, as follows:
Flow rate of TiCl₄ gas: 1 sccm to 100 sccm
Flow rate of Ar gas: 10 sccm to 100,000 sccm, specifically 100 sccm to 20,000 sccm
Flow rate of H₂ gas: 1 sccm to 50,000 sccm, specifically 10 sccm to 10,000 sccm
Processing time: 1 second to 1,800 seconds
Processing temperature: −100 degrees C. to 350 degrees C., specifically 20 degrees C. to 350 degrees C.
Processing pressure: 0.1 Pa to 10,000 Pa, specifically 0.1 Pa to 2,000 Pa.

In step S121 above, the controller 100 may generate a plasma by the plasma generator 51 to facilitate the reaction between the TiCl₄ gas and the H₂ gas. When simultaneously supplying the TiCl₄ gas and the H₂ gas, the controller 100 may plasmarize both the TiCl₄ gas and the H₂ gas.

In addition, in step S121 above, the controller 100 may alternately supply the TiCl₄ gas and the H₂ gas, instead of simultaneously supplying these gases into the processing container 2. In this case, the controller 100 may plasmarize only the H₂ gas among the TiCl₄ gas and the H₂ gas.

After step S121 above, the valves V61 and V64 are closed. At this time, since the valve V62 remains open, the Ar gas is supplied into the processing container 2, and the gas remaining inside the processing container 2 is discharged to the exhaust pipe 22, so that the interior of the processing container 2 is replaced with the atmosphere of Ar.

Subsequently, in step S122 of FIG. 2, the controller 100 opens the valve V63 to supply the O₂ gas into the processing container 2 together with the Ar gas. With the reaction between the O₂ gas and the liquid film W3, the liquid film W3 on the first region W1 is replaced with the first film W4 with a crystalline structure, and the liquid film W3 on the second region W2 is replaced with the second film W5 with a non-crystalline structure.

Specific processing conditions for step S122 above are, for example, as follows:
Flow rate of O₂ gas: 1 sccm to 100,000 sccm, specifically 1 sccm to 10,000 sccm
Flow rate of Ar gas: 10 sccm to 100,000 sccm, specifically 100 sccm to 20,000 sccm
Processing time: 1 second to 1,800 seconds
Processing temperature: −100 degrees C. to 350 degrees C., specifically 20 degrees C. to 350 degrees C.
Processing pressure: 0.1 Pa to 10,000 Pa, specifically 0.1 Pa to 2,000 Pa

In step S122 above, the controller 100 may sequentially execute the plasmarization of the O₂ gas and the like by the plasma generator 51 and the stop of the plasmarization in order to improve the flatness of the liquid film W3. The plasmarization and the stop thereof may be executed in either order.

After step S122 above, the valve V63 is closed. At this time, since the valve V62 remains open, the Ar gas is supplied into the processing container 2 and the gas remaining inside the processing container 2 is discharged to the exhaust pipe 22, so that the interior of the processing container 2 is replaced with the atmosphere of Ar.

Subsequently, in step S13 of FIG. 1, the controller 100 determines whether or not a first cycle has been executed M times (M is an integer of 1 or more). One round of first cycle includes steps S121 and S122 above.

When the number of executions of the first cycle is less than M (NO in step S13), the controller 100 executes the first cycle again. On the other hand, when the number of executions of the first cycle reaches M (YES in step S13), the controller 100 executes step S14.

Subsequently, in step S14 of FIG. 1, the controller 100 opens the valve V65 to supply the ClF₃ gas into the processing container 2 together with the Ar gas. The ClF₃ gas selectively etches the second film W5 with respect to the first film W4. In addition, in step S14 above, the controller 100 may generate plasma by the plasma generator 51, and may also plasmarize the ClF₃ gas.

Specific processing conditions for step S14 above are, for example, as follows:
Flow rate of ClF₃ gas: 1 sccm to 100 sccm
Flow rate of Ar gas: 10 sccm to 100,000 sccm, specifically 100 sccm to 20,000 sccm
Processing time: 1 second to 1,800 seconds
Processing temperature: 30 degrees C. to 350 degrees C., specifically 80 degrees C. to 200 degrees C.
Processing pressure: 0.1 Pa to 10,000 Pa, specifically 0.1 Pa to 2,000 Pa

After step S14 above, the valve V65 is closed. At this time, since the valve V62 remains open, the Ar gas is supplied into the processing container 2 and the gas remaining inside the processing container 2 is discharged to the exhaust pipe 22, so that the interior of the processing container 2 is replaced with the atmosphere of Ar.

In addition, steps S121, S122 and S14 are executed in the interior of the same processing container 2 in the present embodiment, but may be executed in the interiors of different processing containers 2.

Subsequently, in step S15 of FIG. 1, the controller 100 determines whether or not the second cycle has been executed N times (N is a natural number of 1 or more). One round of second cycle includes M first cycles and step S14 executed after the M first cycles.

When the number of executions of the second cycle is less than N (NO in step S15), the controller 100 executes the second cycle again. On the other hand, when the number of executions of the second cycle reaches N (YES in step S15), the controller 100 unloads the substrate W from the processing container 2 in the reverse procedure to the loading of the substrate W into the processing container 2, and terminates the current processing.

In addition, as described above, step S12 may include steps S123 to S127 illustrated in FIG. 4, or may include steps S123 to S128 illustrated in FIG. 5, instead of steps S121 and S122 illustrated in FIG. 2. Hereinafter, an example of the specific processing conditions for steps S123 to S126 will be described.

Specific processing conditions for step S123 above are, for example, as follows:
Flow rate of TiCl₄ gas: 1 sccm to 100 sccm
Flow rate of Ar gas: 10 sccm to 100,000 sccm, specifically 100 sccm to 20,000 sccm
Flow rate of O₂ gas: 1 sccm to 100,000 sccm, specifically 1 sccm to 10,000 sccm
Processing time: 0.1 second to 10 seconds
Processing temperature: 150 degrees C. to 350 degrees C., specifically 250 degrees C. to 350 degrees C.
Processing pressure: 0.1 Pa to 10,000 Pa, specifically 0.1 Pa to 2,000 Pa

Specific processing conditions for step S124 above are, for example, as follows:
Flow rate of Ar gas: 10 sccm to 100,000 sccm, specifically 100 sccm to 20,000 sccm
Flow rate of O₂ gas: 1 sccm to 100,000 sccm, specifically 1 sccm to 10,000 sccm
Processing time: 0.1 second to 10 seconds
Processing temperature: 150 degrees C. to 350 degrees C., specifically 250 degrees C. to 350 degrees C.
Processing pressure: 0.1 Pa to 10,000 Pa, specifically 0.1 Pa to 2,000 Pa

The specific processing conditions for steps S125 and S126 above are the same as the specific processing conditions for step S124 above. However, in step S125, unlike steps S124 and S126, the O₂ gas is plasmarized.

### EXAMPLES

Next, examples will be described. The following examples 1 and 2 below are reference examples, and the following examples 3 to 6 are examples.

### Reference Example 1

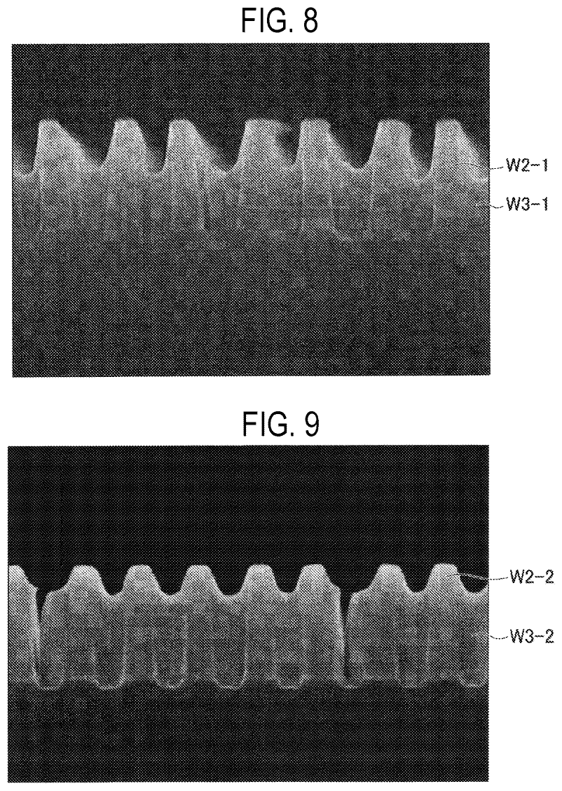

In Reference example 1, as illustrated in FIG. 8, a substrate which is made only of a SiO0 film W2-1 and has an uneven pattern on a substrate surface thereof was prepared, and step S121 of FIG. 2 was executed under processing conditions illustrated in Table 1. It was found that a liquid film W3-1 was formed in a recess of the substrate surface.

TABLE 1

| | | Temperature | | | Time duration | Number of |
|---|---|---|---|---|---|---|
| | Step | [° C.] | Supplied gas | RF | [sec] | repetitions |
| Reference | S121 | 130 | TiCl₄ + H₂ + Ar | ON | 60 | 1 |
| example 1 | | | | | | |

In Table 1, “ON” for “RF” means that a gas was plasmarized by radio-frequency power. The same applies to Tables 2, 3, 5, 6, and 8 below. In addition, “OFF” for “RF” means that the plasmarization of the gas was not executed.

As illustrated in Table 1, in step S121 of Reference example 1, a TiCl₄ gas and an O₂ gas were simultaneously supplied to the substrate surface, and the O₂ gas was plasmarized. As a result, the liquid film W3-1 was formed on the substrate surface, as illustrated in FIG. 8. The formation of a liquid film, rather than a solid film, is evident from the presence of the film only in the recess of the substrate surface and the formation of a meniscus on a film surface.

### Reference Example 2

In Reference example 2, as illustrated in FIG. 9, a substrate which is made only of a SiO film W2-2 and has an uneven pattern on a substrate surface thereof was prepared, and step S121 of FIG. 2 was then executed under processing conditions illustrated in Table 2. It was found that a liquid film W3-2 was formed in a recess of the substrate surface. In Reference example 2, unlike Reference example 1 where the liquid film W3-1 was formed by a plasma CVD method, the liquid film W3-2 was formed by a plasma ALD method.

TABLE 2

| | | Temperature | | | Time duration | Number of |
|---|---|---|---|---|---|---|
| | Step | [° C.] | Supplied gas | RF | [sec] | repetitions |
| Reference | S121a | 130 | SnCl₄ + H₂ + Ar | OFF | 1.0 | 50 |
| example 2 | S121b | 130 | H₂ + Ar | OFF | 1.0 | |
| | S121c | 130 | H₂ + Ar | ON | 1.0 | |
| | S121d | 130 | H₂ + Ar | OFF | 0.1 | |

As illustrated in Table 2, in Reference example 2, the supply of the SnCl₄ gas (step S121a), the purging (step S121b), the supply of the plasmarized O₂ gas (step S121c), and the purging (step S121d) were repeatedly executed 50 times. As a result, the liquid film W3-2 was formed on the substrate surface, as illustrated in FIG. 9. The formation of a liquid film, rather than a solid film, is evident from the presence of the film only in the recess of the substrate surface and the formation of a meniscus on the interface between the film and air.

### Example 3

In Example 3, a substrate having a base film illustrated in Table 4 in a substrate surface thereof was processed under processing conditions illustrated in Table 3.

TABLE 3

| | | Temperature | | | Time duration | |
|---|---|---|---|---|---|---|
| | Step | [° C.] | Supplied gas | RF | [sec] | M, N |
| Example 3 | S121 | 300 | TiCl₄ + H₂ + Ar | ON | 10 | |
| | S122 | 300 | O₂ + Ar | OFF | 60 | |
| | | | | ON | 60 | |
| | S13 | | | | | M = 12 |
| | S14 | 130 | ClF₃ + Ar | OFF | 60 | |
| | S15 | | | | | N = 1 |

As illustrated in Table 3, first, the formation of the liquid film by the plasma CVD method (step S121) and the replacement from the liquid film to a crystalline or non-crystalline film (step S122) was repeatedly executed 12 times. In step S122, as illustrated in Table 3, “OFF” and “ON” for “RF” were made in this order. The duration of one round of “ON” was 60 seconds, and the duration of one round of “OFF” was 60 seconds. As a result, the TiO film was formed on the substrate surface. Subsequently, the etching on the TiO film was executed (step S14).

TABLE 4

| | | | TiO film |
|---|---|---|---|
| | Base film | | Film thickness after |
| | Material | Structure | etching [%] |
| Example 3 | SiO | Non-crystalline | 0.00 |
| | SiN | | 0.00 |
| | AlO | | 0.00 |
| | BN | | 0.00 |
| | Ru | Crystalline | 84.80 |
| | W | | 97.99 |
| | Mo | | 92.83 |
| | TiN | | 92.47 |

In Table 4, the film thickness of the TiO film after etching is represented as the percentage (%) with respect to the film thickness of the TiO film before etching. As is evident from Table 4, the TiO film formed on the base film with a non-crystalline structure was completely removed by etching, whereas the TiO film formed on the base film with a crystalline structure remained after etching. It can be seen that the structure of the TiO film formed on the base film depends on the structure of the base film. It is conceivable that the TiO film with a non-crystalline structure is formed on the base film with a non-crystalline structure, and the TiO film with a crystalline structure is formed on the base film with a crystalline structure.

### Example 4

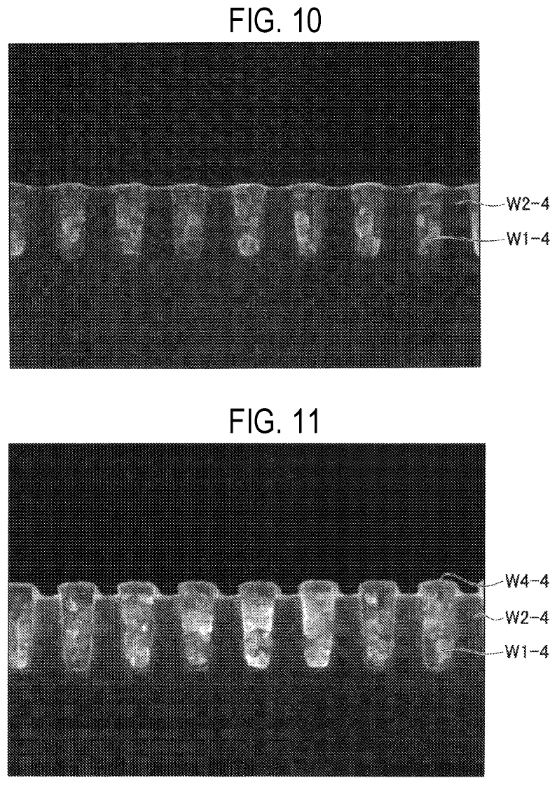

In Example 4, as illustrated in FIG. 10, a substrate having a crystalline Ru film W1-4 and a non-crystalline SiO film W2-4 on a substrate surface thereof was prepared, and was processed under processing conditions illustrated in Table 5.

TABLE 5

| | | Temperature | | | Time duration | |
|---|---|---|---|---|---|---|
| | Step | [° C.] | Supplied gas | RF | [sec] | M, N |
| Example 4 | S121 | 130 | TiCl₄ + H₂ + Ar | ON | 10 | |
| | S122 | 130 | O₂ + Ar | OFF | 60 | |
| | | | | ON | 60 | |
| | S13 | | | | | M = 12 |
| | S14 | 130 | ClF₃ + Ar | OFF | 100 | |
| | S15 | | | | | N = 1 |

As illustrated in Table 5, first, the formation of the liquid film by the plasma CVD method (step S121) and the replacement from the liquid film to crystalline and non-crystalline films (step S122) was repeatedly executed 12 times. In step S122, as illustrated in Table 5, “OFF” and “ON” for “RF” were made in this order. The duration of one round of “ON” was 60 seconds, and the duration of one round of “OFF” was 60 seconds. As a result, the TiO film was formed on the substrate surface. Subsequently, the etching of the TiO film was executed (step S14).

The substrate obtained in Example 4 is illustrated in FIG. 11. As is evident from FIG. 11, a crystalline TiO film W4-4 could remain on the crystalline Ru film W1-4 out of the crystalline Ru film W1-4 and the non-crystalline SiO film W2-4. Most of the non-crystalline SiO film W2-4 was exposed, and a non-crystalline TiO film was completely removed.

### Example 5

In Example 5, a substrate having a base film illustrated in Table 7 on a substrate surface thereof was processed under processing conditions illustrated in Table 6.

TABLE 6

| | | Temperature | | | Time duration | |
|---|---|---|---|---|---|---|
| | Step | [° C.] | Supplied gas | RF | [sec] | K, M, N |
| Example 5 | S123 | 300 | TiCl₄ + O₂ + Ar | OFF | 0.5 | |
| | S124 | 300 | O₂ + Ar | OFF | 1.0 | |
| | S125 | 300 | O₂ + Ar | ON | 0.4 | |
| | S126 | 300 | O₂ + Ar | OFF | 0.1 | |
| | S127 | | | | | K = 300 |
| | S13 | | | | | M = 1 |
| | S14 | 130 | ClF₃ + Ar | OFF | 60 | |
| | S15 | | | | | N = 1 |

As illustrated in Table 6, first, the supply of the TiCl gas (step S123), the purging (step S124), the supply of the plasmarized O₂ gas (step S125), and purge (step S126) was repeatedly executed 300 times. As a result, the TiO film was formed on the substrate surface. Subsequently, the etching on the TiO film was executed (step S14).

TABLE 7

| | | | TiO film |
|---|---|---|---|
| | Base film | | Film thickness after |
| | Material | Structure | etching [%] |
| Example 5 | SiO | Non-crystalline | 0.00 |
| | SiN | | 0.00 |
| | AlO | | 0.00 |
| | Ru | Crystalline | 82.38 |
| | Mo | | 92.15 |
| | TiN | | 100.00 |

In Table 7, the film thickness of the TiO film after etching is represented as the percentage (%) with respect to the film thickness of the TiO film before etching. As is evident from Table 7, the TiO film formed on the base film with a non-crystalline structure was completely removed by etching, whereas the TiO film formed on the base film with a crystalline structure remained after etching. It can be seen that the structure of the TiO film formed on the base film depends on the structure of the base film. It is conceivable that the TiO film with a non-crystalline structure is formed on the base film with a non-crystalline structure, and the TiO film with a crystalline structure is formed on the base film with a crystalline structure.

### Example 6

In Example 6, a substrate having a crystalline Ru film W1-6 and a non-crystalline SiO film W2-6 on a substrate surface thereof was prepared, and was processed under processing conditions illustrated in Table 8.

TABLE 8

| | | Temperature | | | Time duration | |
|---|---|---|---|---|---|---|
| | Step | [° C.] | Supplied gas | RF | [sec] | K, M, N |
| Example 6 | S123 | 250 | TiCl₄ + O₂ + Ar | OFF | 0.5 | |
| | S124 | 250 | O₂ + Ar | OFF | 1.0 | |
| | S125 | 250 | O₂ + Ar | ON | 0.4 | |
| | S126 | 250 | O₂ + Ar | OFF | 0.1 | |
| | S127 | | | | | K = 300 |
| | S13 | | | | | M = 1 |
| | S14 | 130 | ClF₃ + Ar | OFF | 100 | |
| | S15 | | | | | N = 1 |

As illustrated in Table 8, first, the supply of the TiCl₄ gas (step S123), the purging (step S124), the supply of the plasmarized O₂ gas (step S125), and the purging (step S126) was repeatedly executed 300 times. As a result, the TiO film was formed on the substrate surface. Subsequently, the etching of the TiO film was executed (step S14).

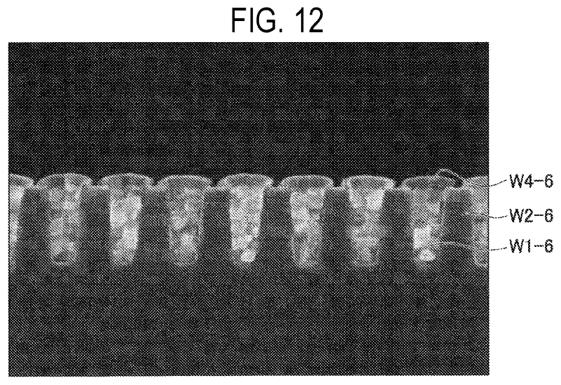

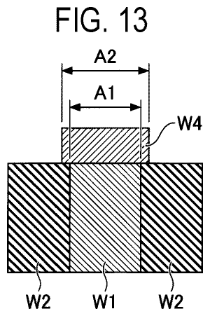

The substrate obtained in Example 6 is illustrated in FIG. 12. As is evident from FIG. 12, a crystalline TiO film W4-6 could remain on the crystalline Ru film W1-6 out of the crystalline Ru film W1-6 and the non-crystalline SiO film W2-6. Most of the non-crystalline SiO film W2-6 was exposed, and the non-crystalline TiO film was completely removed.

### Examples 4 and 6

Table 9 illustrates the following ratio R (%) for Examples 4 and 6. As illustrated in FIG. 13, the ratio R is a ratio of the width A2 of the first film W4 to the width A1 of the first region W1. The ratio R is calculated from Equation “R=A2/A1×100”. In Examples 4 and 6, the first region W1 is made of the Ru film W1-4 or W1-6, and the first film W4 is made of the crystalline TiO film W4-4 or W4-6. The ratio R closer to 100% indicates better transfer accuracy of the structure from the base film to the TiO film.

TABLE 9

| | R [%] |
|---|---|
| Example 4 | 116 |
| Example 6 | 146 |

As is evident from Table 9, the ratio R in Example 4 is closer to 100% than the ratio R in Example 6. In Example 4, the TiO film was formed by the film formation method illustrated in FIG. 2 (including the formation of the liquid film W3), whereas in Example 6, the TiO film was formed by the film formation method illustrated in FIG. 4 (not including the formation of the liquid film W3). From this, it can be seen that the film formation method illustrated in FIG. 2 provides better transfer accuracy of the structure from the base film to the TiO film than the film formation method illustrated in FIG. 4.

Although the embodiments of the film formation method and the film formation apparatus according to the present disclosure have been described above, the present disclosure is not limited to the above embodiments. Various changes, modifications, substitutions, additions, deletions, and combinations are possible within the scope set forth in the claims. These also naturally belong to the technical scope of the present disclosure.

This application claims priority based on Japanese Patent Application No. 2021-129020 filed with the Japan Patent Office on Aug. 5, 2021, and the entire disclosure of Japanese Patent Application No. 2021-129020 is incorporated herein in its entirety by reference.

### EXPLANATION OF REFERENCE NUMERALS

W: substrate, W1: first region, W2: second region, W3: liquid film, W4: first film, W5: second film

1. A film formation method comprising:
(A) preparing a substrate including a first region with a crystalline structure and a second region with a non-crystalline structure, which are defined on a surface of the substrate;
(B) forming a liquid film to cover the first region and the second region;
(C) replacing the liquid film on the first region with a first film of the crystalline structure, and replacing the liquid film on the second region with a second film of the non-crystalline structure; and
(D) selectively etching one of the first film and the second film with respect to a remaining one of the first film and the second film.

2. The film formation method of claim 1, wherein the liquid film contains a metal element.

3. The film formation method of claim 2, wherein (B) includes forming the liquid film by a reaction between a raw material gas containing a metal halide and a reaction gas that reacts with the raw material gas.

4. The film formation method of claim 1, wherein (C) includes using a processing gas that reacts with the liquid film to replace the liquid film on the first region with the first film of the crystalline structure and to replace the liquid film on the second region with the second film of the non-crystalline structure.

5. The film formation method of claim 4, wherein the processing gas includes one or more selected from oxygen, nitrogen, hydrogen, deuterium, and hydride.

6. The film formation method of claim 4, wherein (C) includes plasmarizing the processing gas, and using the plasmarized processing gas to replace the liquid film on the first region with the first film of the crystalline structure and to replace the liquid film on the second region with the second film of the non-crystalline structure.

7. The film formation method of claim 1, wherein (D) includes using a halogen-containing gas to selectively etch the one of the first film and the second film with respect to the remaining one.

8. The film formation method of claim 1, wherein (B), (C), and (D) are executed at a temperature of 350 degrees C. or lower.

9. The film formation method of claim 1, wherein (B) and (C) are repeated.

10. The film formation method of claim 1, wherein (B), (C), and (D) are repeated.

11. The film formation method of claim 1, wherein the substrate is continuously accommodated in a same processing container while executing (B), (C), and (D).

12. A film formation apparatus comprising:
a processing container in which a substrate including a first region with a crystalline structure and a second region with a non-crystalline structure, which are defined on a surface of the substrate, is accommodated;
a holder configured to horizontally hold the substrate with the surface facing upward in an interior of the processing container;
a gas supplier configured to supply a gas to the surface of the substrate held by the holder; and
a controller configured to control the gas supplier,
wherein the controller executes:
forming a liquid film to cover the first region and the second region by supplying, to the surface of the substrate, a raw material gas containing a metal halide and a reaction gas that reacts with the raw material gas;
replacing the liquid film on the first region with a first film of the crystalline structure, and replacing the liquid film on the second region with a second film of the non-crystalline structure by supplying, to the surface of the substrate, a processing gas that reacts with the liquid film; and
supplying, to the surface of the substrate, an etching gas to selectively etch one of the first film and the second film with respect to a remaining one of the first film and the second film.

13. The film formation apparatus of claim 12, further comprising a plasma generator configured to generate a plasma in the interior of the processing container.

14. A film formation method comprising:
(E) preparing a substrate including a first region with a crystalline structure and a second region with a non-crystalline structure, which are defined on a surface of the substrate;
(F) forming a first film of the crystalline structure on the first region and forming a second film of the non-crystalline structure on the second region by alternately supplying, to the surface of the substrate, a raw material gas containing a metal element and a plasmarized reaction gas; and
(G) selectively etching one of the first film and the second film with respect to a remaining one of the first film and the second film.

15. The film formation method of claim 14, wherein the reaction gas is an oxygen-containing gas, a nitrogen-containing gas, or a hydrogen-containing gas.

16. The film formation method of claim 14, wherein (F) includes:
forming the second film of the non-crystalline structure on both the first region and the second region by alternately supplying, to the surface of the substrate, the raw material gas containing the metal element and the plasmarized reaction gas; and
replacing the second film on the first region with the first film by heating the substrate.

17. The film formation method of claim 14, wherein (G) includes using a halogen-containing gas to selectively etch the one of the first film and the second film with respect to the remaining one of the first film and the second film.

18. The film formation method of claim 14, wherein (F) and (G) are executed at a temperature of 350 degrees C. or lower.

19. The film formation method of claim 14, wherein (F) is repeated.

20. The film formation method of claim 14, wherein (F) and (G) are repeated.

21. The film formation method of claim 14, wherein the substrate is continuously accommodated in a same processing container while executing (F) and (G).

22. A film formation apparatus comprising:
a processing container in which a substrate including a first region with a crystalline structure and a second region with a non-crystalline structure, which are defined on a surface of the substrate, is accommodated;
a holder configured to horizontally hold the substrate with the surface facing upward in an interior of the processing container;
a gas supplier configured to supply a gas to the surface of the substrate held by the holder;
a plasma generator configured to generate a plasma in the interior of the processing container; and
a controller configured to control the gas supplier and the plasma generator, wherein the controller executes:
forming a first film of the crystalline structure on the first region and forming a second film of the non-crystalline structure on the second region by alternately supplying, to the surface of the substrate, a raw material gas containing a metal element and a plasmarized reaction gas; and
supplying, to the surface of the substrate, an etching gas to selectively etch one of the first film and the second film with respect to a remaining one of the first film and the second film.
